(19) United States
(12) Patent Application Publication
(10) Pub. No.: US 2014/0173886 A1
(43) Pub. Date: Jun. 26, 2014

(54) METHOD FOR MANUFACTURING LIGHT-EMITTING DIODE LIGHT BAR

(71) Applicant: HON HAI PRECISION INDUSTRY CO., LTD., New Taipei (TW)

(72) Inventor: CHIH-CHEN LAI, New Taipei (TW)

(73) Assignee: HON HAI PRECISION INDUSTRY CO., LTD., New Taipei (TW)

(21) Appl. No.: 14/014,432

(22) Filed: Aug. 30, 2013

(30) Foreign Application Priority Data
Dec. 25, 2012 (TW) 101149894

(51) Int. Cl. H05K 3/30; F21K 99/00

(52) U.S. Cl. CPC H05K 3/303; F21K 9/90
USPC 29/593

(57) ABSTRACT

A method for manufacturing an LED light bar includes steps: a nozzle picks up LEDs pending to be mounted; the electrical parameters of the LEDs detected by the nozzle are stored in a database; then, the nozzle disposes the LED on a substrate; the above steps are repeated until a plurality of LED branches are mounted on the substrate; then, differences of the electrical parameters of the LED branches are calculated according to the electrical parameters in the database; the positions of the LEDs of the LED branches are adjusted to make the electrical parameters of the LED branches equal.

### BACKGROUND

1. Technical Field

The present disclosure relates to a manufacturing method of lighting instruments, more particularly relates to a method for manufacturing light emitting diode (LED) light bar.

2. Description of Related Art

The LED is popular recently. LEDs have advantages such as energy savings, high efficiency, short response time, long life span, and are mercury-free, therefore, LEDs have been widely used in illumination field. During the manufacturing of LED light bar, the LED is mounted on the surface of the strip substrate by a patching machine forming a LED light bar with a plurality of LEDs. An LED light bar usually comprises a plurality of branches which are connected in parallel, and each branch comprises a plurality of LEDs which are connected in series.

As shown in FIG. 1, the light bar 100 comprises a driver chip 10, a first branch 11, a second branch 12 and a third branch 13 extending from the driver chip 10 and connected in parallel. Each branch 11, 12 and 13 is separately composed of ten LEDs which are connected in series. Ideally, the properties of each LED 110, 120 and 130 of each branch 11, 12 and 13 are identical. Thus, the output current from output end 101 of the driver chip 10 through three branches 11, 12 and 13 and back to the driver chip 10, the feedback voltages of three branches should be identical. However, in fact, the voltage error of the LED will drift between 2.8V to 3.2V. Therefore, the feedback voltages of three branches to the driver chip 10 are different. For example, each LED 110 of the first branch 11 is 2.8V, and each LED 120 of the second branch 12 is 3.2V. Thus, a maximum voltage error between the first branch 21 and the second branch 22 will be 4V. Moreover, because the three branches are connected in parallel, and the same output end 101, the voltage of the output end 101 will be the biggest voltage, i.e. 32V. When the output end 101 outputs voltage of 32V, the feedback voltage of the second branch 12 is 0V, however the first branch 11 must bear additional 4V. If the current of the circuit is 1 A, then the driver chip must absorb the efficiency of 4 W. Moreover, the additional consumption of the third branch 13 will be counted in; the driver chip 10 will be more efficient. In this situation, the loss of the light bar 100 is too large; it does not satisfy energy saving needs.

In view of above-mentioned problem, it is necessary to provide a method for manufacturing LED light bar which can avoid the above mentioned deficiencies.

### BRIEF DESCRIPTION OF THE DRAWINGS

FIG. 1 is a schematic view of an LED light bar in accordance with a prior art.

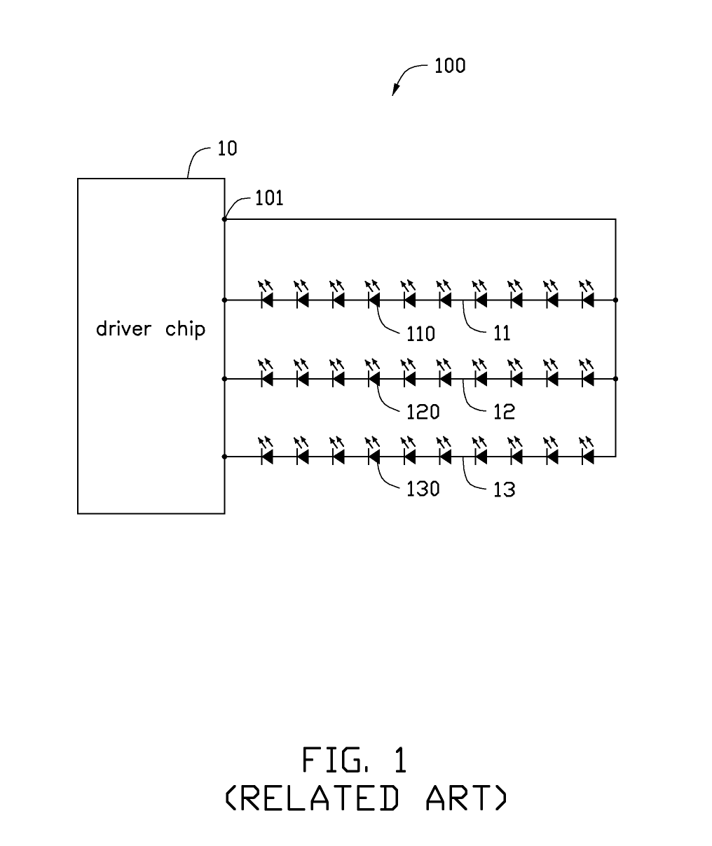

FIG. 2 is a schematic cross-sectional view of a patching machine which is used in a method for manufacturing an LED light bar in accordance with an embodiment of present disclosure.

FIG. 3 is a top view of the patching machine in FIG. 2.

FIG. 4 is a schematic view of a detecting step of a method for manufacturing an LED light bar in accordance with an embodiment of present disclosure.

FIG. 5 is a schematic view of a mounting step of a method for manufacturing an LED light bar in accordance with an embodiment of present disclosure.

FIG. 6 is a flow chart of a method for manufacturing an LED light bar in accordance with an embodiment of present disclosure.

### DETAILED DESCRIPTION

Embodiments will now be described in detail below with reference to the appended figures.

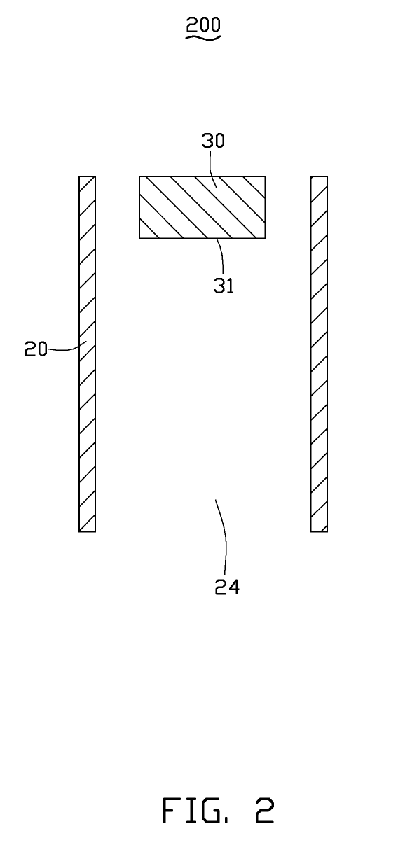

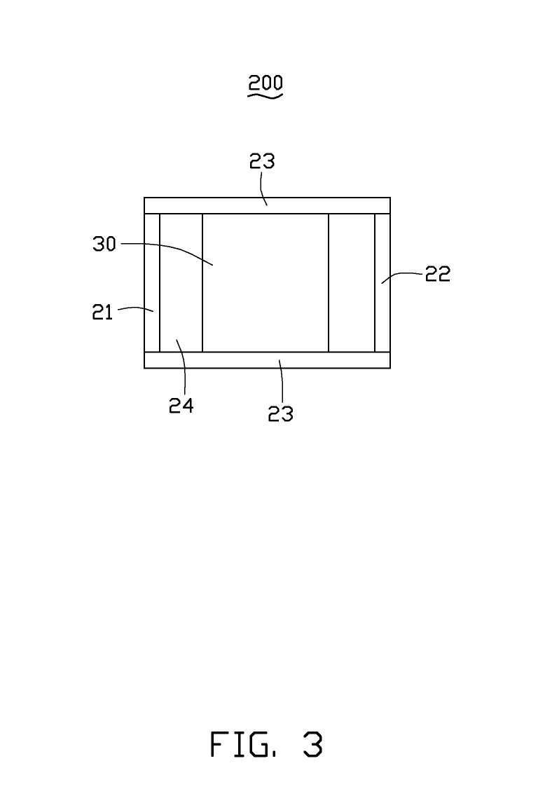

FIG. 2 and FIG. 3 show different angles of a patching machine 200 of a method for manufacturing an LED light bar of an embodiment of present disclosure. The patching machine 200 comprises a nozzle 20 and an optical detector 30.

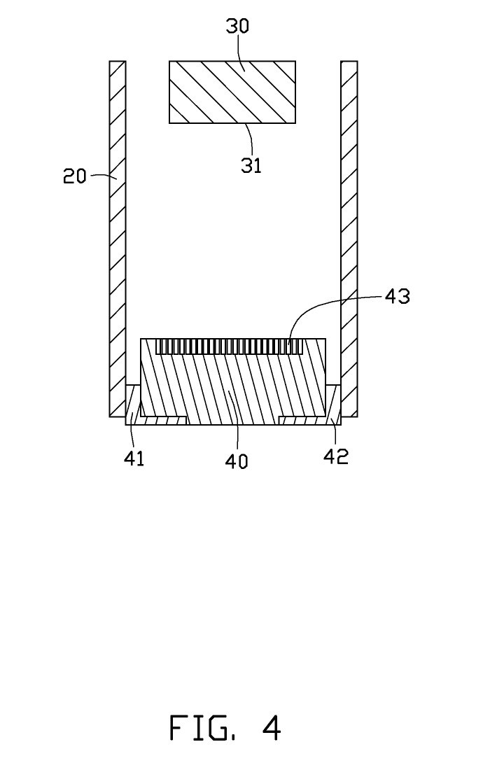

From a top view of FIG. 3, the nozzle 20 appears in a shape of rectangular frame. The nozzle 20 comprises a first electrode 21, a second electrode 22 and two insulating tapes 23. The first electrode 21 and the second electrode 22 are located on two opposite ends of the rectangular frame, and the two insulating tapes 23 connect corresponding ends of the first electrode 21 and the second electrode 22 to form a rectangular frame. The first electrode 21, the second electrode 22, and two insulating tapes 23 cooperatively define a vacuum part 24 positioned in a middle of the nozzle 20. The nozzle 20 can integrally form an insulating barrel, wherein the first electrode 21 and the second electrode 22 are two separate conductive flakes, deposited on opposite sides of the insulating barrel. A suction force generated by a vacuum state of the vacuum part 24 picks up a pending LED. The nozzle 20 can be designed as a holder, i.e. the first electrode 21 and the second electrode 22 are pivotally jointed or through other ways to connect with the two insulating tapes 23; and by the relative movement of the first electrode 21 and the second electrode 22 to clip the pending LED 40 (shown in FIG. 4). The first electrode 21 and the second electrode 22 are made of conductive material. In this embodiment, the first electrode 21 and the second electrode 22 are made of metallic copper surface gilding material, thus the conductive quality can be more efficient.

The optical detector 30 connects with the nozzle 20. The optical detector 30 is positioned at a top end of the vacuum part 24 and between the first electrode 21, the second electrode 22 and two insulating tapes 23. The optical detector 30 attaches to the insulating tape 23, through a wire or other ways to connect with the first electrode 21 and the second electrode 22. The surface of the optical detector 30, which faces the vacuum part 24, is a detecting surface 31. When light is directed into the detecting surface 31, the optical detector 30 detects the light. If necessary, the optical detector 30 can detect the optical parameters, such as brightness or wavelength of the incident light. If high precision optical detections are desired, the optical detector 30 can be connected to a spectrometer through an optical fiber or other ways to analyze wavelength.

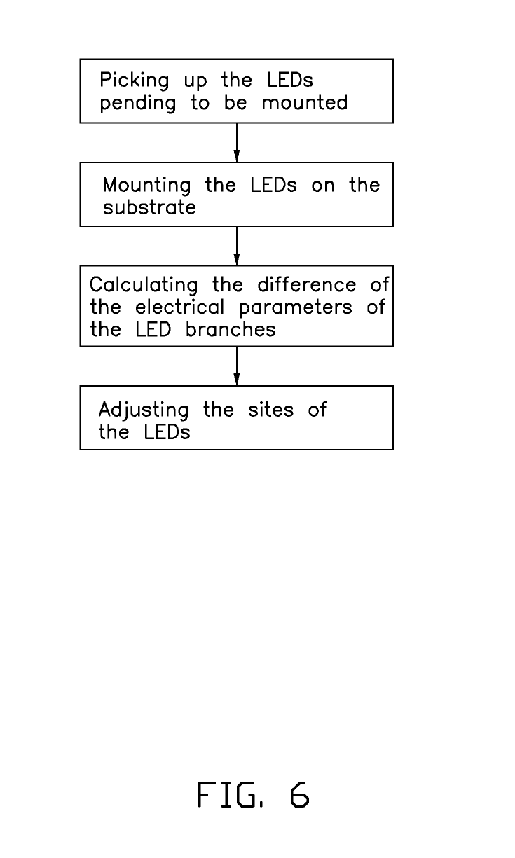

FIGS. 4-6 illustrate the method to manufacture the LED light bar by using the patching machine 200. The patching machine 200 includes an optical detecting function. The method comprises the steps of firstly, the nozzle 20 picks up the LED from a rack; the LED 40 is lit, then electrical parameters of the LED 40 are detected by the first electrode 21 and the second electrode 22, further, the obtained electrical parameters of the LED 40 are stored into a database; then, the LED 40 is mounted on a substrate 50; a plurality of LEDs 40 may be mounted on the substrate 50 to form a plurality of LED branches which are connected in parallel; then, calculating the electrical parameters of each LED 40 stored in the database to determine the voltage value of each branch; the differences of the electrical parameters are determined based on the differences to calculate the best LED position of each branch; further, based on the calculated results, the positions of LEDs of each branches are adjusted to make the electrical values of each branches equal. Wherein, the electrical parameters of LED 40 are stored, the voltage values of each branch and the best positions of LEDs 40 of each branch are calculated, which may be realized by adopting a data processing device such as central processing unit.

The steps of the above-mentioned method will now be described in detail.

As shown in FIG. 4, firstly, the nozzle 20 of the patching machine 200 is used by the vacuum part 24 to suction or clip the terminal ends of the first electrode 21 and the second electrode 22 to pick up the pending LED 40 for mounting. Second, electrodes 41 and 42 of the LED 40 are position on the bottom. The LED 40 also comprises a faceup light emitting surface 43. If the size of the LED 40 is small, the LED 40 can be fixed on the terminal end of the nozzle 20 by suction; and the two electrodes 41. and 42 contact the first electrode 21 and the second electrode 22. The light emitting surface 43 faces the detecting surface 31. Through the first electrode 21 and the second electrode 22 of the nozzle 20, the LED 40 connects to a power supply and emits light to the detecting surface 31. The optical detector 30 displays the detecting result. Based on the detected result, the operator can decide to elect or to abandon the pending LED 40. Or, selection may be by a program setting for the processing to go to next step until the results match the criteria. The first electrode 21 and the second electrode 22 simultaneously register the electrical data of the picked up LED 40 into the data processing device where it is stored.

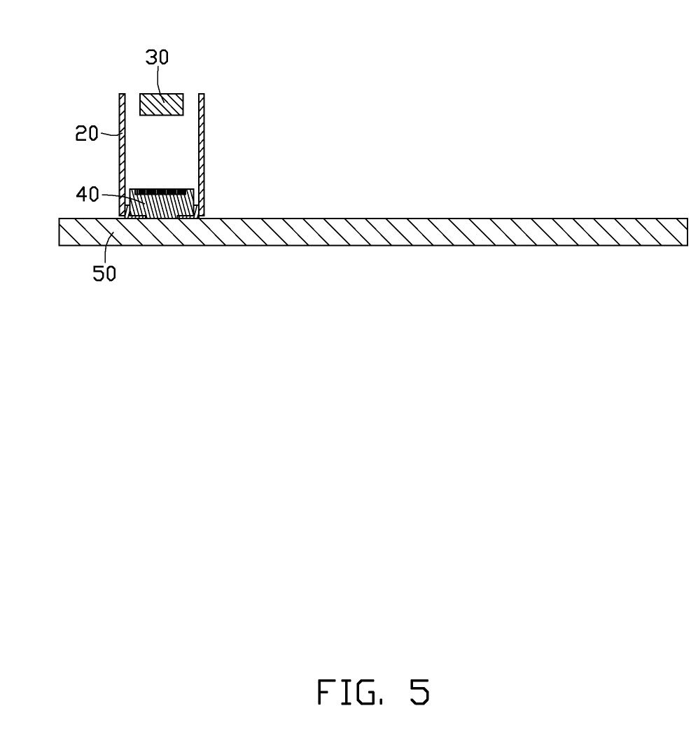

FIG. 5 shows that the substrate 50 is provided for mounting the LEDs 40 once passing the test of the optical detector 30. Repeating the above steps until a number of LEDs 40 are mounted on the substrate 50 to complete the light bar. After the LEDs 40 mounted the data of each branch of the electrical database are summed to obtain the voltage value, then the errors of each branch are compared. In addition, the error result is calculated; so that the most appropriate LED 40 may be selected; adjusting the position of the LED 40 to make the voltage of each branch equal. In the embodiment, adjusting the positions of the LEDs 40 is following an order of adjusting the LEDs with large voltage difference before adjusting the LEDs with small voltage difference.

Compared to conventional manufacturing method of the LED light bar 100, the patching machine 200 used in the manufacturing method of present disclosure has optical detector 30 on the nozzle 20, therefore the optical detection of the LED 40 can be executed during the process of mounting, in order to make sure each LED 40 mounted on the substrate 50 is usable. By using the patching machine 200 to pick up and mount the LED 40, the electrical data of the LED 40 can be record to build up an electrical database of each LED 40 during the process of mounting. After the mounting process, the LED 40 can be adjusted based on the date of the electrical database to make the voltage of each branch of the LED light bar equal, thus the additional consumption from the unequal voltage can be avoided. Moreover, because of the patching machine 200 has a detective function, the electrical data of the lighting LED 40 can be obtained during the picking up process, and it does not require an additional measurement after be mounted. The processes of manufacturing can be reduced.

The above-mentioned embodiments of the present disclosure are intended to be illustrative only. Persons skilled in the art may devise numerous alternative embodiments without departing from the scope of the following claims.

What is claimed is:

1. A method for manufacturing an LED light bar, comprising steps of:
picking up LEDs pending to be mounted by a nozzle, meanwhile detecting electrical parameters of the LED by the nozzle and storing the electrical parameters of the LED in a database;
disposing the LED on a substrate by the nozzle;
repeating the above steps until a plurality of LED branches are mounted on the substrate;
calculating differences of the electrical parameters of the LED branches according of the electrical parameters stored in the database; and
adjusting positions of the LEDs of the LED branches to make the electrical parameters of the LED branches equal.

2. The method as claimed in claim 1, wherein adjusting the positions of the LEDs of branches is following an order of adjusting the LEDs with bigger difference of electrical parameters before adjusting the LED branches with smaller difference of electrical parameters.

3. The method as claimed in claim 1, wherein the electrical parameters of each LED branches are the total voltage value of each LED branches.

4. The method as claimed in claim 1, wherein each LED branches are parallel connecting, and the LEDs of each LED branches are connected in series.

5. The method as claimed in claim 4, wherein the nozzle comprises a first electrode, a second electrode, and at least one insulating tape which separates from the first electrode and the second electrode; when the nozzle picks up the LEDs pending to be mounted, the first electrode and the second electrode contact the LEDs, supply power to the LEDs; and detect the electrical parameters of the LEDs when lighting by the first electrode and the second electrode.

6. The method as claimed in claim 5, wherein the first electrode, the second electrode and the insulating tape of the nozzle cooperatively form a rectangular frame.

7. The method as claimed in claim 6, wherein the nozzle comprises a terminal end which clips the LEDs pending to be mounted and a top end which is away from the terminal end; and the nozzle further comprises an optical detector located on the top end of the nozzle.

8. The method as claimed in claim 7, wherein the optical detector has a detecting surface facing the LED.

9. The method as claimed in claim 5, wherein the nozzle has a vacuum part, by suction of the vacuum part, the nozzle picking up the LEDs pending to he mounted.

10. The method as claimed in claim 9, wherein the vacuum part locates in the rectangular frame which is defined by the first electrode, the second electrode and the insulating tape.
